(19) United States
(12) Patent Application Publication
(10) Pub. No.: US 2018/0077327 A1
(43) Pub. Date: Mar. 15, 2018

(54) IMAGE SENSING MODULE AND CAMERA MODULE

(71) Applicants: LITE-ON ELECTRONICS (GUANGZHOU) LIMITED, Guangzhou (CN); Lite-On Technology Corporation, Taipei (TW)

(72) Inventors: HaiChao Du, Guangzhou (CN); GaoWei Xie, Guangzhou (CN); Chun-Lung Lin, Taipei (TW)

(73) Assignees: LITE-ON ELECTRONICS (GUANGZHOU) LIMITED, Guangzhou (CN); Lite-On Technology Corporation, Taipei (TW)

(21) Appl. No.: 15/435,312

(22) Filed: Feb. 17, 2017

(30) Foreign Application Priority Data
Sep. 14, 2016 (CN) 201610827176.3

(51) Int. Cl. H04N 5/225; H01L 27/146; G02B 5/00; G02B 7/00

(52) U.S. Cl. CPC H04N 5/2254; H01L 27/14623; H01L 27/14629; H01L 27/14618; G02B 7/006; H01L 27/1462; H04N 5/2257; H04N 5/2253; G02B 5/003; H01L 27/14627

(57) ABSTRACT

An image sensing module including a substrate, an image sensor, and a light-extinction layer is provided. The image sensor is disposed on the substrate. The light-extinction layer is at least located on at least part of a surface of a reflective body on the substrate and exposes a sensing area of the image sensor. The reflective body is located on a surface of the substrate at a side of the substrate facing the image sensor. A camera module having the image sensing module is also provided.

### CROSS-REFERENCE TO RELATED APPLICATION

This application claims the priority benefit of China application no. 201610827176.3, filed on Sep. 14, 2016. The entirety of the above-mentioned patent application is hereby incorporated by reference herein and made a part of this specification.

### BACKGROUND OF THE INVENTION

### 1. Field of the Invention

The invention relates to an optical module, and more particularly to an image sensing module and a camera module.

### 2. Description of Related Art

Image sensing modules and camera modules are applied in many fields currently. The camera functions of hand-held electronic devices such as cell phones, tablet computers, or cameras, monitors, driving recorders, driving or reversing monitors, even industrial or medical imaging systems etc., are all inseparable from the image sensing modules and the camera modules.

For improving the imaging quality of the camera module, an optical filter is normally disposed between the lens and the image sensor thereof, and the optical filter is normally installed on a hollow holder. In order to let the effective light beam entering from the lens enter into the image sensor in an unimpeded way, under the consideration of part tolerance and assembly error, the surface area of the optical filter is normally larger than that of the effective area of the image sensor. Due to the above design, under some circumstances, the components and bonding wires around the image sensor may produce useless stray light to interfere with the image formation. To solve the problem, a blackened layer around the optical filter is normally added to block the stray light.

However, the processing requirements of directly blackening the optical filter is high, and the production threshold is higher, and the cost is consequently higher. In addition, a blackened glass doesn't have a commonality in different optical systems. Furthermore, under packaging, filth hard to remove is easily hidden at the combination location of the blacken layer and the glass, e.g. the edge thereof.

### SUMMARY OF THE INVENTION

The invention provides an image sensing module, which can effectively reduce the influence of the stray light on image formation.

The invention provides a camera module, which can effectively reduce the influence of the stray light on image formation.

An image sensing module including a substrate, an image sensor, and a light-extinction layer is provided in an embodiment of the invention. The image sensor is disposed on the substrate. The light-extinction layer is at least located on at least part of a surface of a reflective body on the substrate and exposes a sensing area of the image sensor. The reflective body is located on a surface of the substrate at a side of the substrate facing the image sensor.

A camera module including a substrate, an image sensor, a holder, a lens, an optical film and a light-extinction layer is provided in an embodiment of the invention. The image sensor is disposed on the substrate, the holder is disposed on the substrate, and the lens is disposed on the holder. The optical film is disposed on the holder and located between the lens and the image sensor. The light-extinction layer is at least located on at least part of a surface of a reflective body on the substrate and exposes a sensing area of the image sensor, wherein the reflective body is located between the substrate and the holder.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a schematic cross-sectional view of a camera module according to an embodiment of the invention.

FIG. 2 illustrates a schematic top view of the image sensing module of FIG. 1.

FIG. 3 illustrates a flowchart of the manufacturing method of the camera module in an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

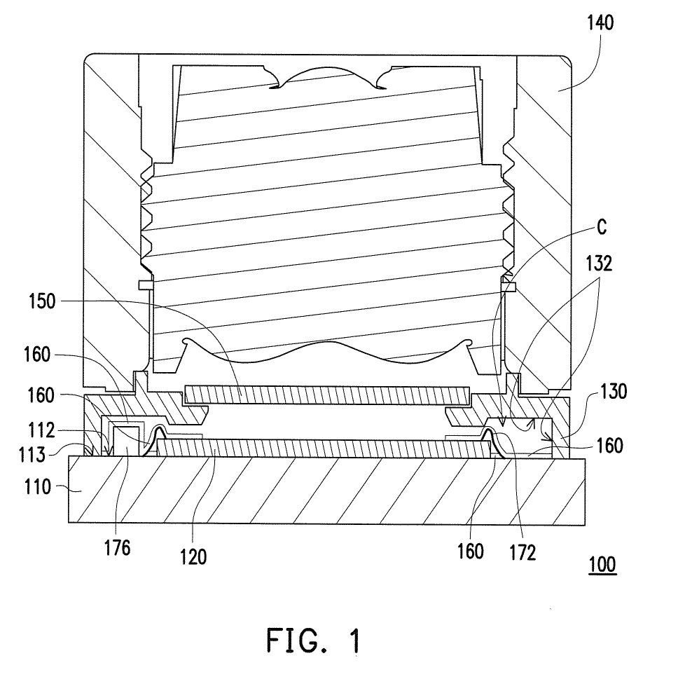

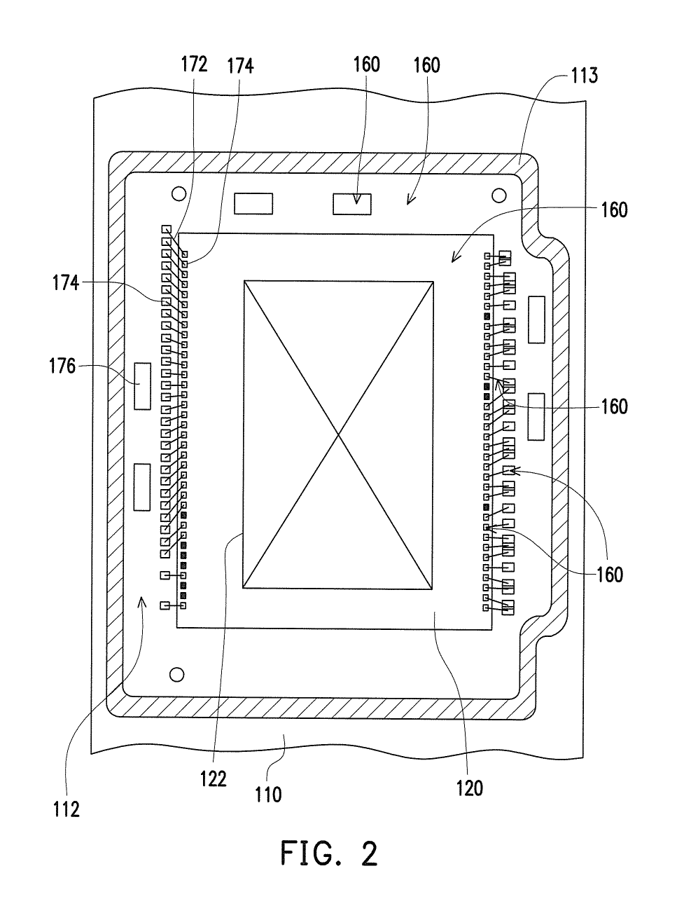

FIG. 1 illustrates a schematic cross-sectional view of a camera module according to an embodiment of the invention, and FIG. 2 illustrates a schematic top view of the image sensing module of FIG. 1. In FIG. 2, for clear illustrations of the image sensor 120, substrate 110 and the reflective body, only the location of the light-extinction layer 160 is shown therein, in contrast to the specific illustration of the light-extinction layer 160 covering a portion of the image sensor 120, a portion of the substrate 110 and the reflective body in FIG. 1. And, the light-extinction layer 160 shown in FIG. 1 is only for the purpose of illustration, and the thickness thereof is not limited. Please referring to FIG. 1 and FIG. 2, the camera module 100 of the embodiment includes a substrate 110, an image sensor 120, a holder 130, a lens base 140 with a lens disposed inside, an optical film 150 and a light-extinction layer 160, wherein the substrate 110, the image sensor 120 and the light-extinction layer 160 may be considered as an image sensing module. The image sensor 120 is disposed on the substrate 110, the holder 130 is disposed on the substrate 110, and the lens base 140 is disposed on the holder 130. In the embodiment, the substrate 110 is a circuit board, a hard substrate or a soft substrate, for example, wherein the circuit board can be a hard circuit board, a flexible circuit board or a substrate formed by a soft circuit film disposed on a hard board. In addition, the image sensor 120 is a complementary metal oxide semiconductor (CMOS) image sensor, or a charge coupled device (CCD), for example.

The optical film 150 is disposed on the holder 130 and located between the lens base 140 and the image sensor 120. In the embodiment, the optical film 150 is an optical filter, such as an infrared cut-off filter, but the invention is not limited thereto. In other embodiments, the optical film 150 may also be a polarizer or any other suitable optical films.

The light-extinction layer 160 is at least located on at least part of a surface of a reflective body on the substrate and exposes a sensing area 122 of the image sensor 120, wherein the reflective body is located between the substrate 110 and the holder 130, for example, located on the surface 112 of the substrate 110 at a side of the substrate 110 facing the image sensor 120 or may also be located in the accommodation space C formed between the substrate 110 and the holder 130. In the embodiment, the reflective body includes a wire 172, a contact pad 174, an electronic component 176, other components able to reflect stray light or a combination thereof, wherein the wire 172 is a conductive bonding wire (for example, a gold wire) between the substrate 110 and the image sensor 120, for example. In addition, the light-extinction layer 160 includes a light-absorbing layer, a surface light-extinction processed layer or a combination thereof. Specifically, the light-extinction layer 160 is for example, additional layer such as a blacken layer or a spray coating layer, or an additional layer formed by deposition reaction of color element (such as electroplating layers), and so on. In addition, the light-extinction layer 160 may also be a matte surface layer formed by application of physical or chemical treatment on the surface of the reflective body, wherein the physical treatment is surface roughening treatment, for example, and the chemical treatment is potion corrosion treatment or the above-mentioned deposition reaction of the color element (such as electroplating), for example. The above-mentioned light-extinction layer 160 of various kinds all have the effect of suppressing the stray light reflected by the reflective body.

In the image sensing module and camera module 100 of the embodiment of the invention, since the light-extinction layer 160 is at least located on at least part of the surface of the reflective body on the substrate 110 and the reflective body is located on the surface of the substrate 110 at a side of the substrate 110 facing the image sensor 120 or located between the substrate 110 and the holder 130, therefore, in the embodiment of the invention, the stray light can be effectively suppressed from the source of the stray light (that is, the reflective body), and from the processing's point of view, the influence of the stray light on image formation is more thoroughly reduced. In such a way, in the image sensing module and the camera module 100 of the embodiment, through the blackening or extinction process on both the area and the components capable of producing stray light around sensing area 122 of the image sensor 120, the stray light is less likely to enter the sensing area 122 of the image sensor 120 between the substrate 110 and the holder 130, so that the influence of the stray light on image formation is effectively reduced.

In the embodiment, the light-extinction layer 160 covers at least part of a surface 112 of the substrate 110 at a side of the substrate 110 facing the image sensor 120. In addition, the light-extinction layer 160 may also be located on the surface of the image sensor 120 other than the sensing area 122 of the image sensor 120. In an embodiment, the light-extinction layer 160 may cover the non-light sensing area of the image sensor 120 or the reflecting surface on the substrate 110, such as bare conductive wires, glossy ink or contact pads. For example, the surface 112 of the substrate 110 facing the image sensor 120 has a holder disposing area 113 surrounding the image sensor 120 and supporting the holder 130, wherein the light-extinction layer 160 exposes the holder disposing area 113, that is, no light-extinction layer 160 is disposed on the holder disposing area 113. Such a circumstance is adapted to the case of the light-extinction layer 160 being the above-mentioned additional layer, so that the holder 130 and the substrate 110 may have good adhesion or combination. In an embodiment, the light-extinction layer 160 may cover all of the surface inside the holder disposing area 113 other than the sensing area 122, e.g. all of the area between the holder disposing area 113 and the sensing area 122 as illustrated in FIG. 2. However, in another embodiment, the light-extinction layer 160 may cover all of the surface inside the holder disposing area 113 other than the sensing area 122, cover the holder disposing area 113 and cover the portion of the surface 112 outside the holder disposing area 113; for example, the light-extinction layer 160 covers all of the area between the holder disposing area 113 and the sensing area 122, the holder disposing area 113 and the area of the substrate 110 on the outer periphery of the holder disposing area 113 as illustrated in FIG. 2. When the light-extinction layer 160 is a non-additional layer, and is, for example, the above-mentioned matte or rough surface processed physically or chemically, the light-extinction layer 160 may be provided on the holder disposing area 113, and with this, the holder 130 and the substrate 110 can have good adhesion or combination. However, this invention is not limited thereto, the meaning of the above-mentioned “the light-extinction layer 160 is at least located on at least part of the surface of the reflective body on the substrate 110” includes the following situations: when the light-extinction layer 160 is located on at least part of the surface of the reflective body on the substrate 110, the light-extinction layer 160 located on part of or all of the surface of the reflective body is included, and the light-extinction layer 160 located on some of the reflective bodies and not on other reflective bodies is included. This is because in a plurality of reflective bodies, some of the location of the reflective bodies is more likely to let the stray light reflected by the reflective body enter the sensing area 122, then the light-extinction layer 160 is more in need of being disposed on the surface of these reflective bodies so as to reduce the situation. However, when the location of other reflective bodies is less likely to let the stray light reflected by the reflective body enter the sensing area 122, then the light-extinction layer 160 is not necessary to be disposed on the surface of these reflective bodies. In addition, the first “at least” in the above-mentioned “the light-extinction layer 160 is at least located on at least part of the surface of the reflective body of the substrate 110” means that the light-extinction layer 160 may be not only located on at least part of the surface of the reflective body of the substrate 110, but also cover at least part of the surface 112 of the substrate 110 at the side of the substrate 110 facing the image sensor 120 as mentioned above, or be located on a surface other than the sensing area 122 of the image sensor 120, or be located on at least part of the surface of the reflective body in the accommodation space C between the substrate 110 and the holder 130. However, in an embodiment, the light-extinction layer 160 can also be not located on at least part of the surface of the reflective body of the substrate 110, but cover at least part of the surface 112 of the substrate 110 at a side of the substrate 110 facing the image sensor 120 instead, or be located on a surface other than the sensing area 122 of the image sensor 120.

In the embodiment, the optical film 150 doesn't have frame-shaped light-absorbing coating. For example, when the optical film 150 is an optical filter, the frame-shaped blacken layer may be not provided thereon. Since the improving method about the influence of the stray light on image formation in this embodiment is achieved by providing effective suppression of the stray light from the source of the stray light (for example, the reflective body in the accommodation space C), therefore, the frame blackening process with higher processing difficulty is not necessary to be performed on the optical filter, and the processing difficulty and cost of the optical filter can be significantly reduced. Consequently, the camera module 100 of the embodiment can have a lower cost. In addition, because the optical film 150 in the embodiment doesn't have the frame-shaped light-absorbing coating, therefore, the problem of the filth difficult to remove being hidden at the combination location between the blacken layer and the optical filter substrate in the conventional technology will not occur. In addition, since there is no need to dispose the frame-shaped light-absorbing coating with a size corresponding to the sensing area 122 of the image sensor 120 on the optical film 150, the optical film 150 can be adapted to an image sensor 120 of various kinds. Besides, not only the simulation of the path of the stray light is simplified, the greater applicability is also provided to various camera modules 100.

In the embodiment, a light-absorbing layer or a surface extinction processed layer is disposed in the inner surface 132 of the holder 130, wherein the light-absorbing layer or the surface extinction processed layer can be the above-mentioned examples of the light-absorbing layer or surface extinction processed layer and processing method of the reflective body. In addition, when the holder 130 is produced by a light-absorbing material, the holder 130 may be for example a black holder, and the surface extinction processed layer may be textures on the inner surface 132 of the holder 130.

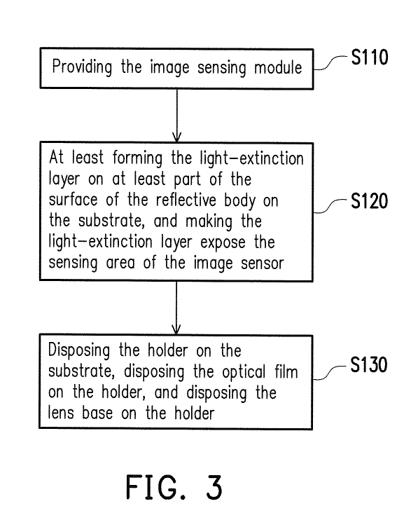

FIG. 3 illustrates a flowchart of a manufacturing method of the camera module in an embodiment of the invention. Please referring to FIGS. 1, 2 and 3, the manufacturing method of the camera module of the embodiment can be configured to produce the camera module 100 of FIGS. 1 and 2, and the following steps are included therein. First, a step S110 is performed: an image sensing module is provided, wherein the image sensing module includes the substrate 110 and the image sensor 120 disposed on the substrate 110. And, a step S120 is then performed: the light-extinction layer 160 is formed at least on at least part of the surface of the reflective body on the substrate 110, and the light-extinction layer 160 is made to expose the sensing area 122 of the image sensor 120. In the embodiment, the method of making the light-extinction layer 160 expose the sensing area 122 of the image sensor 120 is performing shield spraying on the sensing area 122, for example. For instance, a film is used to cover the sensing area 122, and the spray coating process is performed on other areas on the substrate 110. In addition, the method of making the light-extinction layer 160 expose the holder disposing area 113 may also be performing the shield spraying on the holder disposing area. For instance, a film is used to cover the holder disposing area 113, and the spray coating process is performed on other areas on the substrate 110. Moreover, the portion of the substrate 110 or the reflective body without disposition of the light-extinction layer 160 can all be achieved by shield spraying. The various possible position and variation of the light-extinction layer 160 have already been described in detail in the preceding embodiment, and is not repeated herein.

Afterwards, a step S130 is performed; the holder 130 is disposed on the substrate 110, the optical film 150 is disposed on the holder 130, and the lens base 140 is disposed on the holder 130, then the production of the camera module 100 can be completed. By the above production method, the camera module 100 able to reduce the influence of the stray light on the image formation, having low cost, easy to produce and with high versatility as mentioned above can be produced.

Based on the above, in the image sensing module and camera module of the embodiment of the invention, since the light-extinction layer is at least located on at least part of the surface of the reflective body on the substrate, and the reflective body is located on the surface of the substrate at a side of the substrate facing the image sensor, or located between the substrate and the holder, therefore, in the embodiment of the invention, the stray light can be effectively suppressed from the source of the stray light (that is, the reflective body). In such a way, in the image sensing module and the camera module of the embodiment of the invention, the influence of the stray light on image formation can be effectively reduced.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. An image sensing module, comprising:
a substrate;
an image sensor, disposed on the substrate; and
a light-extinction layer, at least located on at least part of a surface of a reflective body on the substrate and exposing a sensing area of the image sensor, wherein the reflective body is located on a surface of the substrate at a side of the substrate facing the image sensor.

2. The image sensing module according to claim 1, wherein the reflective body comprises a wire, a contact pad, an electronic component or a combination thereof.

3. The image sensing module according to claim 1, wherein the light-extinction layer is further located on a surface of the image sensor outside the sensing area of the image sensor or covers at least part of the surface of the substrate at the side of the substrate facing the image sensor.

4. The image sensing module according to claim 1, wherein the light-extinction layer comprises a light-absorbing layer, a surface extinction processed layer or a combination thereof.

5. The image sensing module according to claim 1, further comprises a holder, disposed on the substrate, wherein the reflective body is located between the substrate and the holder.

6. A camera module, comprising:
a substrate;
an image sensor, disposed on the substrate;
a holder, disposed on the substrate;
a lens base with a lens, disposed on the holder,
an optical film, disposed on the holder, and located between the lens and the image sensor; and
a light-extinction layer, at least located on at least part of a surface of a reflective body on the substrate and exposing a sensing area of the image sensor, wherein the reflective body is located between the substrate and the holder.

7. The camera module according to claim 6, wherein the reflective body comprises a wire, a contact pad, an electronic component or a combination thereof.

8. The camera module according to claim 7, wherein the reflective body is located on a surface of the substrate at a side of the substrate facing the image sensor.

9. The camera module according to claim 7, wherein the light-extinction layer is further located on a surface of the image sensor outside the sensing area of the image sensor or covers at least part of a surface of the substrate at a side of the substrate facing the image sensor.

10. The camera module according to claim 7, wherein the light-extinction layer comprises a light-absorbing layer, a surface extinction processed layer or a combination thereof.
